(19) United States
(12) Patent Application Publication
(10) Pub. No.: US 2010/0008575 A1
(43) Pub. Date: Jan. 14, 2010

(54) System and Method for Tuning a Sampling Frequency

(76) Inventors: Bing Ouyang, Plano, TX (US); Amit Mittal, Bangalore (IN); Troy Lane Ethridge, Bedford, TX (US)

Correspondence Address: TEXAS INSTRUMENTS INCORPORATED, P O BOX 655474, M/S 3999, DALLAS, TX, 75265, US

(21) Appl. No.: 12/172,360

(22) Filed: Jul. 14, 2008

(51) Int. Cl. G06K 9/00; H04N 5/66; H03M 1/12

(52) U.S. Cl. 382/168; 348/739; 348/572; 348/E05.133

(57) ABSTRACT

A system and method for tuning a sampling frequency. A method comprises detecting a sampling frequency of an analog image signal, generating a set of histograms from samples of pixels from the analog image signal, using the set of histograms to determine whether the detected sampling frequency is substantially equal to a natural sampling frequency of the analog image signal, and sampling the analog image signal at the detected sampling frequency to produce image data. The samples are taken at the detected sampling frequency and at a different sampling phase for each of the histograms, and each histogram is for samples from a single image.

### CROSS-REFERENCE TO RELATED APPLICATIONS

This application is related to the following co-assigned patent applications: U.S. Ser. No. 12/101,685, filed Apr. 11, 2008, entitled “System and Method for Detecting a Sampling Frequency of an Analog Video Signal,” Attorney Docket Number TI-65743, filed ______ /2008, entitled “System and Method for Clock Offset Detection,” which applications are hereby incorporated herein by reference.

### TECHNICAL FIELD

The present invention relates generally to a system and method for displaying images, and more particularly to a system and method for tuning a sampling frequency.

### BACKGROUND

In many modern image display systems, image frames of an analog image signal, such as analog video, analog computer graphics, analog DVDs, analog game console output, and so forth, may be digitized prior to being displayed. Digitizing the image frames of the analog image signal may enable processing of the image frames by image processing hardware in the image display system. The processing performed by the image processing hardware may improve image quality, reduce image noise, enhance desired properties of the image, deemphasize undesired properties of the image, and so on, for example.

The digitizing may include sampling the analog image signal without prior knowledge of a sampling frequency or sampling phase using an analog to digital converter (ADC). In order to properly digitize the images in the analog image signal, a sampling frequency generally must be detected. If the sampling frequency is incorrectly detected, then when the digitized images are displayed, the resulting images may be distorted at best or completely incomprehensible at worse.

In general, there may be two different techniques used in the detection of the sampling frequency of image frames of an analog image signal. A first technique, commonly referred to as timing based detection of sampling frequency, may involve the measuring of synchronization signals or synchronization characteristics present in the analog image signal and then comparing the measured synchronization signals or synchronization characteristics with known image standard values to determine the sampling frequency of the analog image signal. The known image standard values may be stored in a memory, a table of some form, or a mathematical expression. An advantage of timing based detection of sampling frequency may be that the detection of sampling frequency may be achieved quickly; typically, the sampling frequency may be detected within several image frames.

A second technique, commonly referred to as data based detection of sampling frequency, may involve analysis of image content present in the analog image signal to determine the sampling frequency of the analog image signal. In general, data based detection of sampling frequency involves detecting a left edge and a right edge of an image frame using frame data content detection techniques and then adjusting a sampling clock to determine the sampling frequency of the analog image signal. An advantage of data based detection of sampling frequency may be that the sampling frequency of a wide range of analog image signals may be detected, even when the sampling frequency of the analog image signals deviates from the sampling frequency of analog image signal of known video standards.

### SUMMARY OF THE INVENTION

These and other problems are generally solved or circumvented, and technical advantages are generally achieved, by embodiments of a system and a method for tuning a sampling frequency.

In accordance with an embodiment, a method for generating image data from an analog image signal is provided. The method includes detecting a sampling frequency of the analog image signal, generating a set of histograms from samples of pixels from the analog image signal, using the set of histograms to determine whether the detected sampling frequency is substantially equal to a natural sampling frequency of the analog image signal, and sampling the analog image signal at the detected sampling frequency to produce image data. The samples are taken at the detected sampling frequency and at a different sampling phase for each of the histograms, and wherein each histogram is for samples from a single image.

In accordance with another embodiment, a method for displaying images from an analog image signal is provided. The method includes detecting a sampling frequency of the analog image signal, determining if the detected sampling frequency is substantially equal to a natural sampling frequency of the analog image signal using a set of histograms, selecting a second sampling phase of the detected sampling frequency using the set of histograms, sampling the analog image signal at the detected sampling frequency and the second sampling phase to produce second samples, image processing the second samples, and displaying the processed second samples. The set of histograms are based on adjacent pixel differences of samples of pixels from the analog image signal, with the samples taken at the detected sampling frequency and at a different sampling phase for each of the histograms. Each histogram is for samples from a single image;

In accordance with another embodiment, a display system is provided. The display system includes a display that produces images by modulating light based on image data, an image input providing an analog image signal including the image data, an image processing unit coupled to the image input, and a controller coupled to the image processing unit and to the display. The controller controls the operation of the display based on the image data. The image processing unit digitizes the analog image signal and determines if a sampling frequency used to digitize the analog image signal is substantially equal to a natural sampling frequency of the analog image signal. The image processing unit determines if the sampling frequency and the natural sampling frequency are substantially equal from a plurality of histograms of adjacent pixel difference values of samples taken at the sampling frequency and at different sampling phases for each histogram, and wherein each histogram is for samples from a single image.

An advantage of an embodiment is that image frame memory may not be required. Therefore, image frame memory may be used in the displaying of images and other image display functions, rather than determining and/or tuning the sampling frequency.

A further advantage of an embodiment is that if an initial attempt to determine and/or tune the sampling frequency failed, the determining and/or tuning of the sampling may continue without interfering with image display functions.

Yet another advantage of an embodiment is that moving images may be used in addition to fixed images in the determining and/or tuning of the sampling frequency. This may increase the probability of successfully determining and/or tuning the sampling frequency.

Yet another advantage of an embodiment is that memory control logic and task switching logic may be simplified since the determining and/or tuning of the sampling frequency does not need exclusive access to image frame memory. This may lead to an overall simpler design with reduced complexity and potentially increased reliability.

Yet another advantage of an embodiment is that the time required to correctly configure an ADC's sampling frequency and sampling phase may be significantly reduced, which may lead to a shorter time between a connecting of an image source and a displaying of images. This may help to improve viewer experience and overall satisfaction.

The foregoing has outlined rather broadly the features and technical advantages of the present invention in order that the detailed description of the embodiments that follow may be better understood. Additional features and advantages of the embodiments will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1a and 1b are diagrams of waveforms from two temporally consecutive images and samples of the waveforms taken at an incorrect sampling frequency or sampling phase;

FIGS. 2a and 2b are diagrams of waveforms from two temporally consecutive images and samples of the waveforms taken at a correct sampling frequency and optimum sampling phase;

FIG. 3a is a diagram of a waveform and samples of the waveform taken at an incorrect sampling frequency or sampling phase;

FIG. 3b is a diagram of a waveform and samples of the waveform taken at a correct sampling frequency and optimum sampling phase;

FIG. 4a is a diagram of display system;

FIG. 4b is a diagram of an image processing unit;

FIG. 5 is a diagram of a sequence of events in generating image data;

FIG. 6 is a diagram of a sequence of events in determining and eliminating a sampling frequency offset;

FIGS. 7a and 7b are diagrams of data plots of frame to frame differences and adjacent pixel differences of an analog image signal;

FIG. 8a is a diagram of an image divided into a number of columns of width W;

FIGS. 8b and 8c are diagrams of adjacent pixel differences for vertical columns of different widths;

FIG. 9a is a diagram of a sequence of events in the verifying of a sampling frequency;

FIG. 9b is a diagram of a sequence of events in creating histograms;

FIG. 9c is a diagram of a sequence of events in selecting an optimum sampling phase;

FIGS. 10a through 10g are diagrams of data plots of a variety of metrics computable from histograms; and

FIG. 11 is a diagram of a sequence of events in displaying images.

### DETAILED DESCRIPTION OF ILLUSTRATIVE EMBODIMENTS

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The embodiments will be described in a specific context, namely a digital micromirror device (DMD) microdisplay-based image projection display system connected to an analog image source, such as a computer. The invention may also be applied, however, to other forms of analog image sources, such as analog video tape, analog DVDs, analog game console output, analog electronic video sources, such as multimedia players and sources, and so on. Furthermore, the invention may also be applied to other forms of microdisplay-based image projection display systems, such as deformable micromirrors, liquid crystal on silicon (LCOS), ferroelectric liquid-crystal-on-silicon, reflective, transmissive, and transflective liquid crystal displays (LCD), and so forth. Additionally, the invention may be applied to other types of video display systems, including direct view display systems, such as those using plasma, LCD, cathode ray tube (CRT), and so on, displays. In general, the invention may be applied to applications wherein there is a desire to display an analog image source.

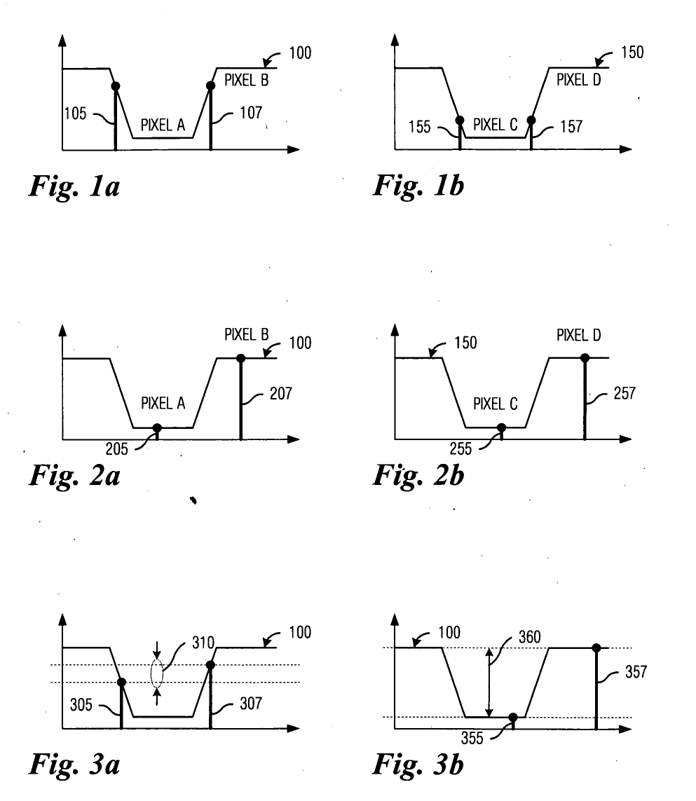

With reference now to FIG. 1a, there is shown a diagram illustrating a waveform 100 showing several pixels of a first image. Also shown in FIG. 1a are two samples of the pixels, a first sample 105 and a second sample 107, taken of the waveform 100 with an incorrect sampling frequency or sampling phase. Due to the incorrect sampling frequency or sampling phase, an analog to digital converter (ADC) may sample the waveform 100 on edges of pixels. This may produce samples of similar amplitude, although the pixels being sampled may have different amplitudes. FIG. 1b illustrates a waveform 150 showing several pixels of a second image along with a third sample 155 and a fourth sample 157, taken of the waveform 150. The third sample 155 and the fourth sample 157 may be taken by the ADC with the same incorrect sampling frequency and sampling phase as used by the ADC to sample the waveform 100, producing the first sample 105 and the second sample 107, and at substantially the same spatial location as the first sample 105 and the second sample 107 respectively.

Due to an intrinsic temporal jitter that may be present in the ADC (and a sampling circuit containing the ADC) as well as in the waveforms 100 and 150, there may be a large difference in amplitude between the first sample 105 and the third sample 155, and the second sample 107 and the fourth sample 157, respectively. Because of the temporal jitter, a small change in sampling point may result in a large difference in amplitude when the sampling points are occurring at the edges of the analog waveforms.

FIGS. 2a and 2b illustrate the waveforms 100 and 150 and samples of the waveforms 100 and 150 taken by the ADC with a correct sampling frequency and optimum sampling phases. Samples of the waveform 100 include a first correct sample 205, and a second correct sample 207, while samples of the waveform 150 include a third correct sample 255, and a fourth correct sample 257. Since the correct sampling frequency and optimum sampling phases are used, the pixels are sampled in stable portions of the waveforms and the amplitudes of the samples are substantially the same. Therefore, temporal jitter may not have as large an impact on the amplitudes of the samples.

As described above, a frame to frame difference may be used to provide an indication of the use of an incorrect sampling frequency and/or sampling phase to sample an analog image signal. An adjacent pixel difference may also exhibit similar behavior when an incorrect sampling frequency and/or sampling phase are used to sample the analog image signal. With an incorrect sampling frequency and/or sampling phase, a difference in amplitude between two adjacent pixels may be smaller than a difference in amplitude between two adjacent pixels sampled with correct sampling frequency and sampling phase. An advantage in using adjacent pixel difference is that there may not be a need to buffer images in memory since the adjacent pixel differences may be computed dynamically as the images are being received. This may free up image memory for uses other than sampling frequency detection and verification.

FIG. 3a illustrates the waveform 100 sampled by an ADC using an incorrect sampling frequency or sampling phase, producing a sample 305 and a sample 307. An amplitude difference between the sample 305 and the sample 307 is shown as amplitude span 310. FIG. 3b illustrates the waveform 100 sampled by an ADC using a correct sampling frequency and sampling phase, producing a sample 355 and a sample 357. An amplitude difference between the sample 355 and the sample 357 is shown as amplitude span 360. Therefore, samples of adjacent pixels may potentially have an amplitude difference that is smaller than expected when the samples are made using an incorrect sampling frequency and/or sampling phase.

The amplitude span 310 of the samples taken by the ADC using an incorrect sampling frequency or sampling phase may be a fraction of the amplitude span 360 of the samples taken by the ADC using a correct sampling frequency and sampling phase, with the amplitude span 360 being on the order of an amplitude difference between pixels having different values. A disparity in the amplitude differences between pixels sampled using an incorrect sampling frequency or sampling phase and a correct sampling frequency and sampling phase may be used to determine or adjust the correct sampling frequency and sampling phase. The difference in the amplitudes of adjacent pixels may be referred to as adjacent pixel difference.

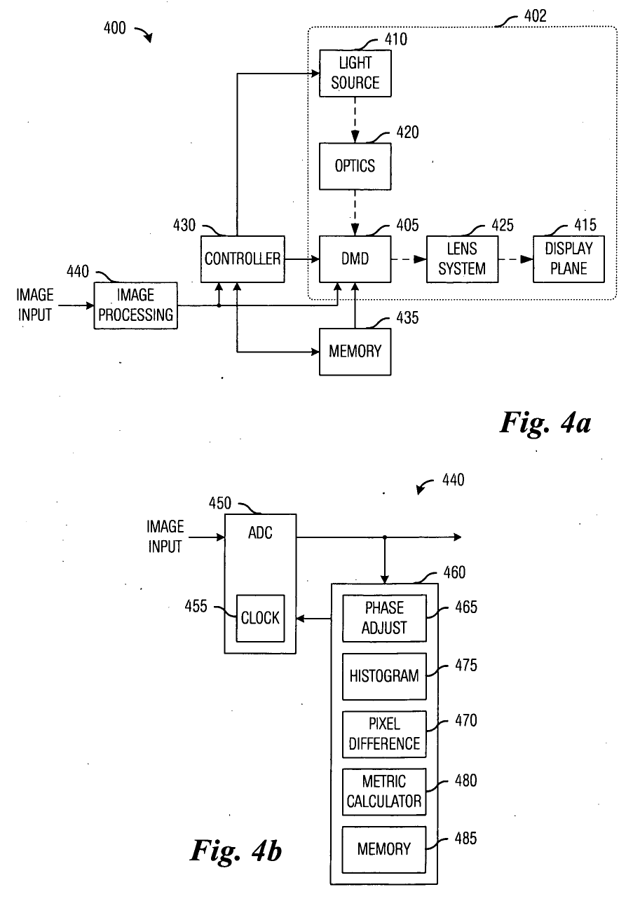

FIG. 4a illustrates an image display system 400. The image display system 400 includes an imaging unit 402 that may be used to display images. The image display system 400 shown in FIG. 4a is a DMD-based projection display system and the imaging unit 402 includes a DMD 405 that modulates light produced by a light source 410. The DMD 405 is an example of a microdisplay or an array of light modulators. Other examples of microdisplays may include transmissive or reflective liquid crystal, liquid crystal on silicon, ferroelectric liquid-crystal-on-silicon, deformable micromirrors, and so forth. In a microdisplay, a number of light modulators may be arranged in a rectangular, square, diamond shaped, and so forth, array.

Each light modulator in the microdisplay may operate in conjunction with the other light modulators in the microdisplay to modulate the light produced by the light source 410. For example, in the DMD 405, each light modulator is a pivoting mirror that generally pivots between one of two positions depending on image data being displayed. In a first position, the light modulator reflects light from the light source onto a display plane 415 and in a second position, the light modulator reflects light away from the display plane 415. The light modulated by the DMD 405 may be used to create images on the display plane 415. The image projection display system 400 also includes an optics system 420, which may be used to collimate the light produced by the light source 410 as well as to collect stray light, and a lens system 425, which may be used to manipulate (for example, focus) the light reflecting off the DMD 405.

If the image display system 400 is a different type of image display system, then the imaging unit 402 may be correspondingly different. For example, if the image display system 400 uses a different form of microdisplay, then the imaging unit 402 may include the different microdisplay in place of the DMD 405. Alternatively, if the image display system 400 is a direct view system instead of a projection system, then the imaging unit 402 may not include the display plane 415 and potentially the lens system 425. Furthermore, if the image display system 400 is a cathode ray tube-based direct view system, then the imaging unit 402 may not include the light source 410, the optics system 420, the lens system 425, or the display plane 415. If the image display system 400 is a cathode ray tube-based projection system, then the imaging unit 402 may include the lens system 425 and the display plane 415.

The DMD 405 may be coupled to a controller 430, which may be responsible for loading image data into the DMD 405, controlling the operation of the DMD 405, providing micromirror control commands to the DMD 405, controlling the light produced by the light source 410, and so forth. A memory 435, which may be coupled to the DMD 405 and the controller 430, may be used to store the image data, as well as configuration data, color correction data, and so forth.

The image display system 400 includes an image processing unit 440. The image processing unit 440 may be used to digitize images from an analog image signal provided by an image input. The image processing unit 440 also includes a clock configured to provide a reference signal at a sampling frequency to time the digitizing of the images from the analog image signal. Additionally, the image processing unit 440 includes the ability to tune the sampling frequency by changing a sampling phase of the reference signal provided by the clock, computing a metric or measure to evaluate the samples of the analog image signal sampled at the sampling frequency and the sampling phase, and selecting a sampling phase yielding a metric or measure meeting or exceeding expectations. The image processing unit 440 may also determine a sampling frequency offset that may exist between a natural sampling frequency of the analog image signal and the sampling frequency used to sample the analog image signal. The natural sampling frequency of the analog image signal may be a sampling frequency that when used to time the sampling of the analog image signal may produce image samples that accurately represent the analog image signal.

The operation of the image processing unit 440, including verifying a sampling frequency, tuning a sampling phase, determining a sampling frequency offset, and so forth, may occur without requiring the use of image frame memory since it may not be necessary to store the images or samples of the image. This may allow for the use of image frame memory for image display purposes, such as displaying images, processing image data, other image display functions, and so forth. Additionally, images containing moving content may be used by the image processing unit 440 rather than requiring images contain substantially motionless content.

FIG. 4b illustrates a detailed view of the image processing unit 440. The image processing unit 440 includes an analog to digital converter (ADC) 450 that may be used to digitize (sample) the analog image signal provided by the image input. The digitizing (sampling) performed by the ADC 450 may be timed by a reference signal provided by a clock 455. The reference signal provided by the clock 455 may be at a sampling frequency of the analog image signal. The sampling frequency of the analog image signal may be detected by a sampling frequency detect unit. The sampling frequency detect unit may be contained in the controller 430, in another processing unit, or it may be its own processing unit. The sampling frequency detect unit may use a timing based sampling frequency detection technique, a data based sampling frequency detection technique, or a combination of both to detect the sampling frequency of the analog image signal. Please refer to a co-assigned U.S. patent application entitled “System and Method for Detecting a Sampling Frequency of an Analog Video Signal,” Ser. No. 12/101,685, filed Apr. 11, 2008, which patent application is hereby incorporated herein by reference, for a detailed discussion of the detection of the sampling frequency of the analog image signal.

The image processing unit 440 also includes a sampling frequency and sampling phase tuning unit (SFSPT) 460. The SFSPT 460 may be used to adjust the sampling phase of the sampling frequency to help ensure that the sampling of the analog image signal by the ADC 450 is occurring at stable portions of pixels in the analog image signal. The SFSPT 460 includes a phase adjust unit 465. The phase adjust unit 465 may be used to adjust the sampling phase of the ADC 450. The phase adjust unit 465 may adjust the sampling phase of the ADC 450 by changing the reference signal provided by the clock 455. Alternatively, the phase adjust unit 465 may directly changing the sampling phase being used by the ADC 450.

Generally, the ADC 450 may sample the analog image signal at a sampling frequency as provided by the clock 455. However, in addition to the sampling frequency, the sampling performed by the ADC 450 may be dependent on the sampling phase, which may specify a sampling offset or delay from a reference point. Sampling at the reference point may be referred to as sampling with zero sampling phase. A number of sampling phase points may depend on the design of the ADC 450, with 16, 32, 64, and so forth, being typical values for the number of sampling phase points.

The SFSPT 460 also includes a pixel difference unit 470. The pixel difference unit 470 may be used to compute pixel intensity differences of samples of pixels that are adjacent on a horizontal line of the image (horizontal pixel difference). The pixel difference unit 470 may also compute pixel intensity differences of samples of pixels that are adjacent on a vertical line of the image (vertical pixel difference). Alternatively, the pixel difference unit 470 may compute a difference in grayscale in a specified color (for example, red, green, blue, or combinations thereof) between two adjacent pixels. For example if pixel A's grayscale values for the colors (red, green, blue) are (2, 10, 20) and pixel B's grayscale values for the same colors are (230, 240, 250), then the pixel difference unit 470 may compute the difference in grayscale to be (−228, −230, −230). The pixel difference unit 470 may compute the difference in grayscale for all colors, or some specified colors.

The SFSPT 460 also includes a histogram unit 475. The histogram unit 475 may be used to compute a histogram of an image in the analog image signal. The histogram unit 475 may compute a histogram of pixel intensities of pixels in the image by incrementing counts associated by pixel intensity bins depending on the intensity of samples of the pixels made by the ADC 450. The histogram unit 475 may compute histograms of adjacent pixel differences computed by the pixel difference unit 470, for example.

The SFSPT 460 also includes a metric calculator unit 480. The metric calculator unit 480 may compute a metric or a measure of data computed by the histogram unit 475 of data produced by the pixel difference unit 470. Examples of metrics computed by the metric calculator unit 480 may include sum, average, standard deviation, cross correlation between various histograms of individual sampling phases, and so forth. The metric or the measure may allow for a comparison of a quality of the samples made by the ADC 450 with specified sampling frequency and sampling phase. The sampling frequency and sampling phase that results in the best metric or measure, for example, may be selected. A memory 485 may be used to store the results of the metric calculator unit 480 as well as the samples created by the ADC 450, the histogram unit 475, and/or the pixel difference unit 470. The memory 485 may be significantly smaller than a memory that may be used for buffering images.

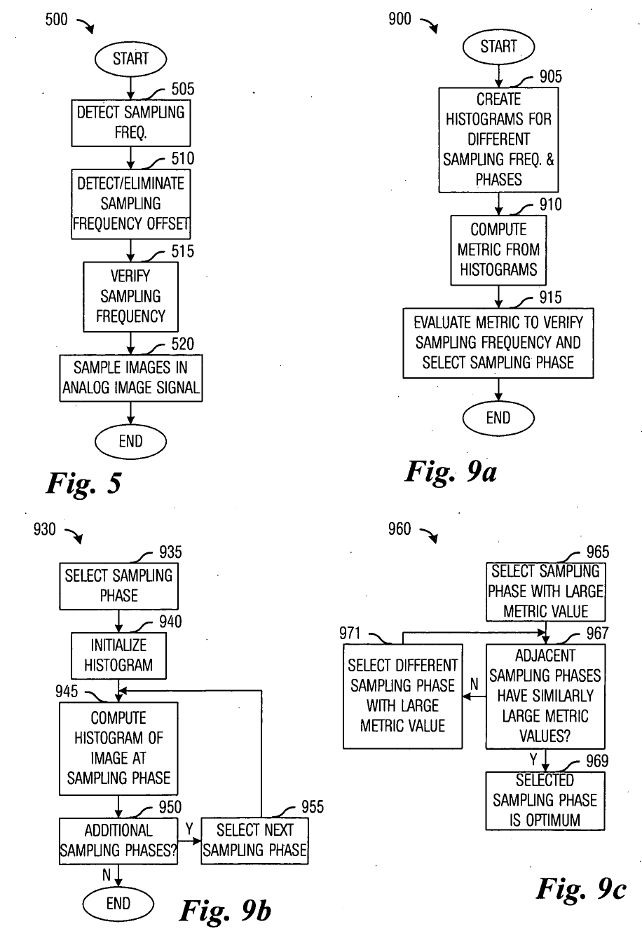

FIG. 5 illustrates a sequence of events 500 in the generating of image data for a display system. The generating of image data may be used to provide samples of images provided by an analog image signal to the display system so that the images may be displayed by the display system. The generating of image data may occur when a new analog image signal is provided to a display system, when the display system loses lock on the analog image signal, when the display system fails to determine the sampling frequency of an existing analog image signal, and so forth. The generating of image data may continue while the display system is displaying images and may stop if the display system is turned off, reset, enters a sleep or suspend mode, or so forth.

The generating of image data may begin with a detecting of a sampling frequency of the analog image signal provided by an image input (block 505). The detecting of the sampling frequency may be performed using a timing based sampling frequency detection technique, a data based sampling frequency detection technique, and/or a combination of both. Please refer to a co-assigned U.S. patent application entitled “System and Method for Detecting a Sampling Frequency of an Analog Video Signal,” Ser. No. 12/101,685, filed Apr. 11, 2008 for a detailed discussion of the detection of the sampling frequency of the analog image signal.

The generating of image data for the display system may continue with a detecting/eliminating of a sampling frequency offset (block 510). The detecting/eliminating of the sampling frequency offset may also not require exclusive use of image frame memory.

As discussed previously, there may be a sampling frequency offset between a sampling frequency of the analog image signal (the natural sampling frequency) and a sampling frequency used to time the ADC 450. When images sampled by the ADC 450 timed with a sampling frequency that has a sampling frequency offset with the sampling frequency of the analog image signal are displayed, image artifacts may be visible on the images. The image artifacts may appear visually as a vertical interference pattern. The vertical interference pattern may be periodic with the period of the vertical interference pattern being related to the sampling frequency offset. If the sampling frequency offset is detected, then the sampling frequency offset may be eliminated (or reduced).

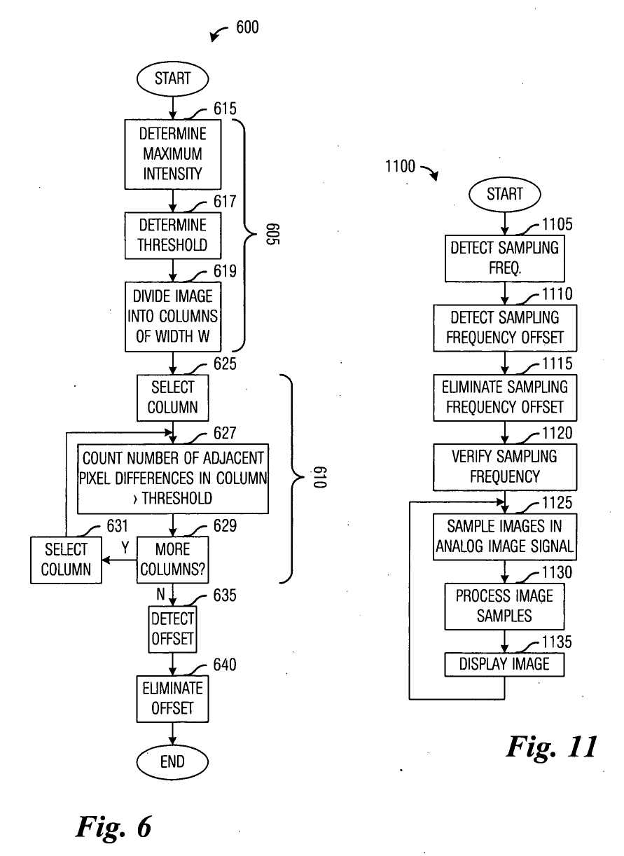

FIG. 6 illustrates a sequence of events 600 in the detecting/eliminating of a sampling frequency offset. The determining/eliminating of the sampling frequency offset may be performed after the sampling frequency has been detected and verified. The sequence of events 600 may be an implementation of the detecting/eliminating the sampling frequency offset block 510.

The sequence of events 600 may include an initialization phase 605 and a data generation phase 610. The initialization phase 605 may include a determining of a maximum pixel intensity of an image of the analog image signal (block 615). The maximum intensity may be used to determine a threshold for use in the data generation phase 610 (block 617). For example, the threshold may be defined as a percentage of the maximum intensity. An overly large value may result in a discarding of a large number of pixels in the image, while a value that is too small may result in a counting of too many pixels in the image. Potential values may include values in a range between 70 to 90 percent of the maximum intensity. A preferred value may be about 80 percent of the maximum intensity.

After the threshold has been determined, then the image may be divided into columns of width W (block 619). Values for W may range from one (1) and up. If W is set to one (1), then the columns may substantially be a single pixel wide. The value of W may be set based on an expected value of the sampling frequency offset. For example, if the expected value of the sampling frequency offset is large, then W may be set to a small value, such as less than eight (8). If the expected value of the sampling frequency offset is small, then W may be set to a large value, such as larger than eight (8). Smaller values of W may allow for better resolution of the clock offset, while larger values of W may allow for better filtering of high frequency variation/noises.

The data generation phase 610 may begin with a selecting of a column (block 625). For example, a very first column of the image may be selected. Alternatively, a very last column of the image may be selected. After selecting the column, a count of adjacent pixel differences in the column that exceed the threshold may be performed (block 627). After the count of adjacent pixel differences in the column exceeding the threshold has been completed, then if additional columns remain unselected (block 629) another column may be selected (block 631) and the count of adjacent pixel differences may be repeated (block 627). Preferably a column adjacent to the column may be selected, however, any column that has not had its adjacent pixel differences counted may be selected.

After the counting of the adjacent pixel differences for each column in the image has been performed (block 629), then the sampling frequency offset may be detected (block 635). For example, the sampling frequency offset may be detected using the AMDF function. The detecting of the sampling frequency offset is described in detail in a co-assigned U.S. patent application entitled “System and Method for Detecting a Sampling Frequency of an Analog Video Signal,” Ser. No. 12/101,685, filed Apr. 11, 2008. After the detecting of the sampling frequency offset has been determined, the sampling frequency offset may be eliminated (or reduced) (block 640). The sampling frequency offset may be eliminated by adjusting the clock 455 in the ADC 450. After eliminating the sampling frequency offset, the sequence of events 600 may terminate.

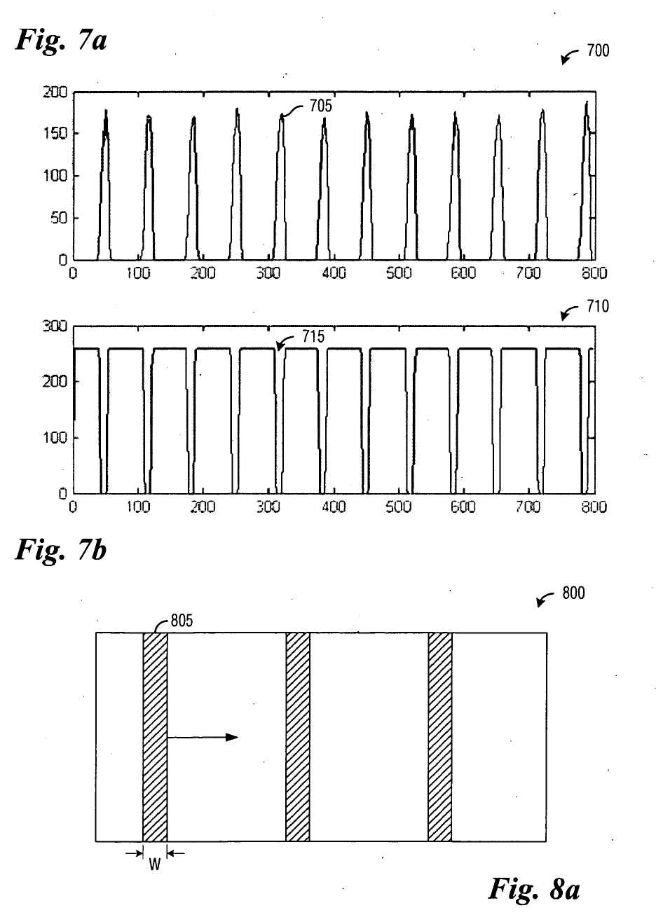

FIG. 7a illustrates a data plot 700 of frame to frame difference computed from an exemplary analog signal, wherein the samples of an exemplary analog signal are created by the ADC 450 timed with an incorrect sampling frequency. The frame to frame difference may be used in conjunction with an average magnitude difference function (AMDF) to compute a sampling frequency offset. Please refer to co-assigned U.S. patent application entitled “System and Method for Clock Offset Detection,” Attorney Docket Number TI-65743, filed ______ /2008, for a detailed description of AMDF and the computing of the sampling frequency offset.

FIG. 7b illustrates a data plot 710 of adjacent pixel difference computed from an exemplary analog signal, wherein the samples of an exemplary analog signal are created by the ADC 450 timed with an incorrect sampling frequency. The data plot 700 and data plot 710 may be complementary in nature, with a peak, such as a peak 705, in the data plot 700 corresponding to a valley, such as a valley 715, in the data plot 710. Since the data may be substantially similar, it may be possible to use the adjacent pixel difference in place of the frame to frame difference to compute the sampling frequency offset.

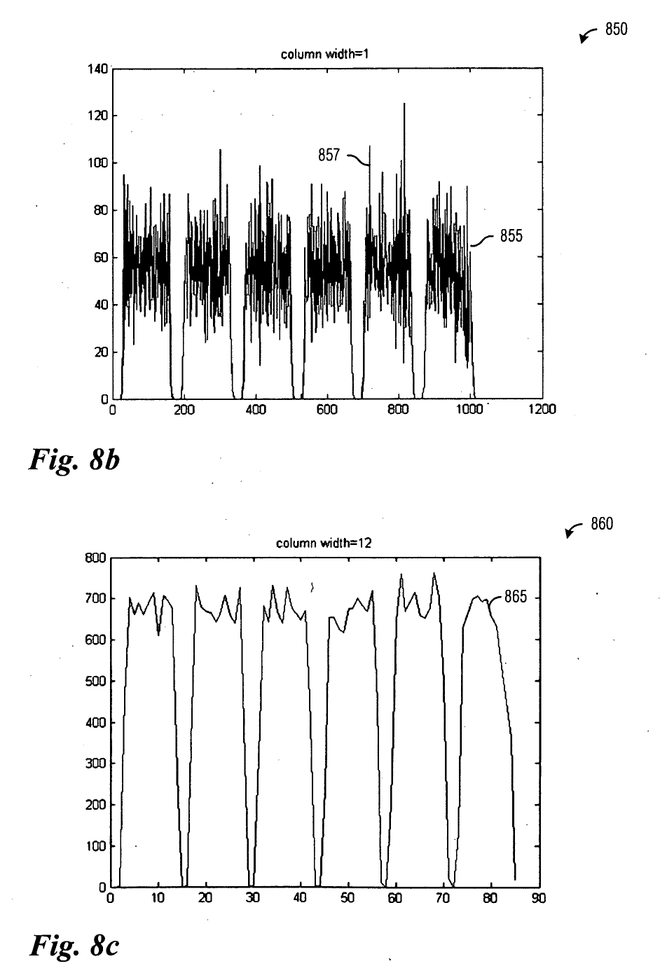

FIG. 8a illustrates a diagram of an image 800, wherein the image 800 has been divided into a number of columns of width W, such as column 805. The division of the image 800 into columns of width W may allow for a column-wise evaluation of adjacent pixel difference. After completing a column-wise evaluation of adjacent pixel difference for one column, another column may be evaluated. For example, the process may follow a left to right direction over the image 800. FIG. 8b illustrates a data plot 850 of adjacent pixel difference counts for an image in the analog image signal, wherein a column width (W) of one (1) is used. The data plot 850 illustrates a series of peaks, such as peak 855 and peak 857. The peaks display a considerable amount of noise, which may make it difficult to detect individual peaks. FIG. 8c illustrates a data plot 860 of adjacent pixel difference counts for an image in the analog image signal, wherein a column width (W) of 12 is used. The use of a larger column width may reduce the noise on the peaks, such as peak 865, which may make the peak 865 easier to detect.

Referring back now to FIG. 5, after the detecting and eliminating of a sampling frequency offset (block 510), the sampling frequency may be verified (block 515). The verification of the sampling frequency may be used to ensure that the detected sampling frequency may be about equal to a natural sampling frequency of the analog image signal. The verification of the sampling frequency may not require exclusive use of image frame memory. Furthermore, the verification of the sampling frequency may enable a selection of a sampling phase of an ADC, such as the ADC 450, to ensure accurate sampling of the analog image signal. The selected sampling phase may be referred to as an optimum sampling phase.

FIG. 9a illustrates a sequence of events 900 in the verifying of a sampling frequency. The sequence of events 900 may be an implementation of the verifying of a sampling frequency block 515 of the sequence of events 500. The verifying of the sampling frequency may begin with a creating of histograms (block 905). The creating of histograms may include the creating of a histogram for each possible sampling phase of an ADC, such as the ADC 450. In general, the creating of a histogram for a single sampling phase of the ADC 450 may be performed using samples taken from an image. Since the image is not stored, the creating of the histogram for a single sampling phase may preclude the use of the image in the creation of histograms for other sampling phases. Therefore, if the creation of a histogram involves samples of an entire image, then each histogram may be created from a different image.

Alternatively, an image may be partitioned into horizontal parts and each horizontal part may be sampled with a different sampling phase with the samples being used to create the histograms. For example, if there are a total of 32 sampling phases and a histogram is to be created for each sampling phase, an image may be partitioned into four horizontal parts with each of the four horizontal parts being sampled with a different sampling phase. Therefore, a total of eight images may be used in the creation of the 32 histograms. In another example, the image may be partitioned into 32 horizontal parts and all 32 histograms may be created from a single image. The number of horizontal parts per image may be determined by factors such as, an amount of image data per horizontal part, image size, a settling time of an ADC used to perform the sampling, hardware and software capabilities, desired hardware and software complexity, and so forth.

An advantage available in creating histograms for each possible sampling phase of the ADC 450 may be that there may be more information available to help make a decision regarding the verification of the sampling frequency and the selection of the sampling phase. Alternatively, histograms may be created for a subset of the possible sampling phases.

Generally, the computing of a histogram for a sampling phase may occur within a single image time and a storage requirement for storing a histogram may be significantly smaller than storing an image. However, with a typical number of sampling phases being on the order of 16, 32, 64, and so forth, the creation of a histogram for each sampling phase may result in a large number histograms (which may potentially result in a significant amount of computation time and/or memory storage space). Therefore, an alternative embodiment may create histograms for every J-th sampling phase, wherein J may be an integer value with typical values being 2, 3, 4, 5, 6, 7, 8, and so on. The value of J may be dependent on factors, such as a time limitation to resolve the sampling frequency, memory size, histogram size, histogram resolution, image size, available histogram computation time, available computation power, and so forth.

FIG. 9b illustrates a sequence of events 930 in the creating of histograms. The sequence of events 930 may be an implementation of the creating of histograms block 905 of the sequence of events 900. The creating of histograms may begin with a selecting of a sampling phase of the ADC 450, with the ADC 450 set at a sampling frequency (block 935). A typical order of progression may involve selecting a lowest (or highest) sampling phase of the ADC 450 and then continue by selecting a next lowest (or next highest) sampling phase and so on. As the sampling phase is changed, the sampling frequency may remain constant. However, the order of the selecting of the sampling phase may not have any effect on the creating of the histograms.

After selecting the sampling phase, an initializing of a histogram may be performed (block 940). The initialization of the histogram may be used to specify thresholds, partition the histogram into bins, and so forth. For example, the initialization of the histogram may include: determining (measuring) a maximum pixel intensity for pixels in an image, establishing a low threshold based on the maximum pixel intensity (for example, low threshold may be equal to 0.7 * maximum pixel intensity), and dividing an intensity range from the low threshold to the maximum pixel intensity into N bins, wherein N is a number of bins in the histogram, and so on. Values other than 0.7 may be used to establish the low threshold, for examples, values in a range of 0.6 to 0.8 may be typical values for establishing the low threshold. The initialization may be repeated for each histogram created or a single initialization may be used for all histograms.

After the histogram has been initialized, the histogram may be computed from samples of the image, wherein the samples of the image are made by the ADC 450 at the sampling frequency and the selected sampling phase (block 945). The histogram may be computed using adjacent pixel difference computations, with the computations being performed by a pixel difference unit, such as the pixel difference unit 470. In an adjacent pixel difference computation, the pixel difference unit 470 may compute a difference between adjacent pixels (either horizontally adjacent or vertically adjacent). Then, a bin corresponding to a difference range containing the value of the adjacent pixel difference computation may be incremented. For example, if there are four bins, with Bin#1 corresponding to difference range (0, 0.24), Bin#2 corresponding to difference range (0.25, 0.49), Bin#3 corresponding to difference range (0.50, 0.74), and Bin#4 corresponding to difference range (0.75, 1.0), if the value of the adjacent pixel difference computation is 0.36, then Bin#2 may be incremented.

After the histogram has been computed for the selected sampling phase (block 945), a check may be made to determine if there are additional sampling phases (block 950). If there are additional sampling phases, then a new sampling phase may be selected (block 955) and a histogram for the new sampling phase may be computed (block 945). The computing of the histogram may involve samples of each pixel in a single image. Since the image may not be buffered or stored in memory, if multiple histograms are to be computed, then multiple images may be required. If there are no additional sampling phases, then the creating of histograms may terminate.

Returning now to FIG. 9a, after the histograms for the different sampling phases have been created (block 905), a variety of metrics or measures may be computed (block 910). The metrics and/or measures may be used to help in the verifying of the sampling frequency. A metric and/or measure may make it easier to evaluate the samples of the analog image signal being made by the ADC 450 at various sampling phases. A metric and/or measure may be able to take advantage an expected amplitude difference between samples taken by the ADC 450 with a correct sampling frequency and sampling phase compared to an expected amplitude difference between samples taken by the ADC 450 with an incorrect sampling frequency and/or sampling phase as discussed previously. Examples of metrics and/or measures may include summation, average, standard deviation, cross correlation, and so forth.

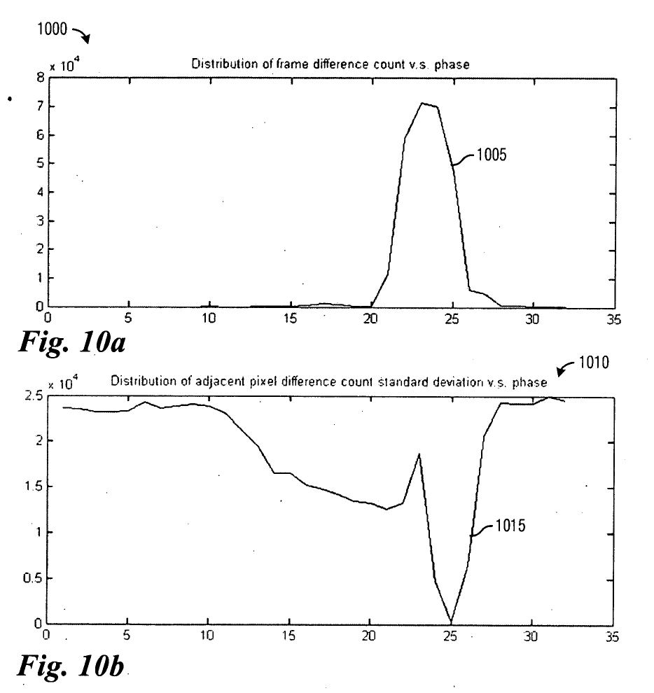

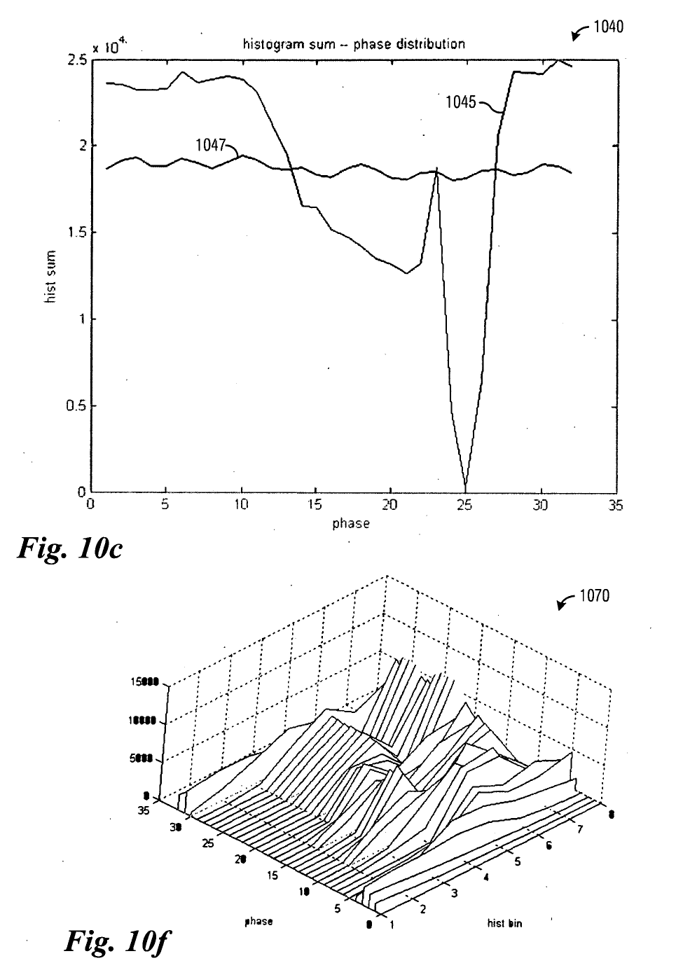

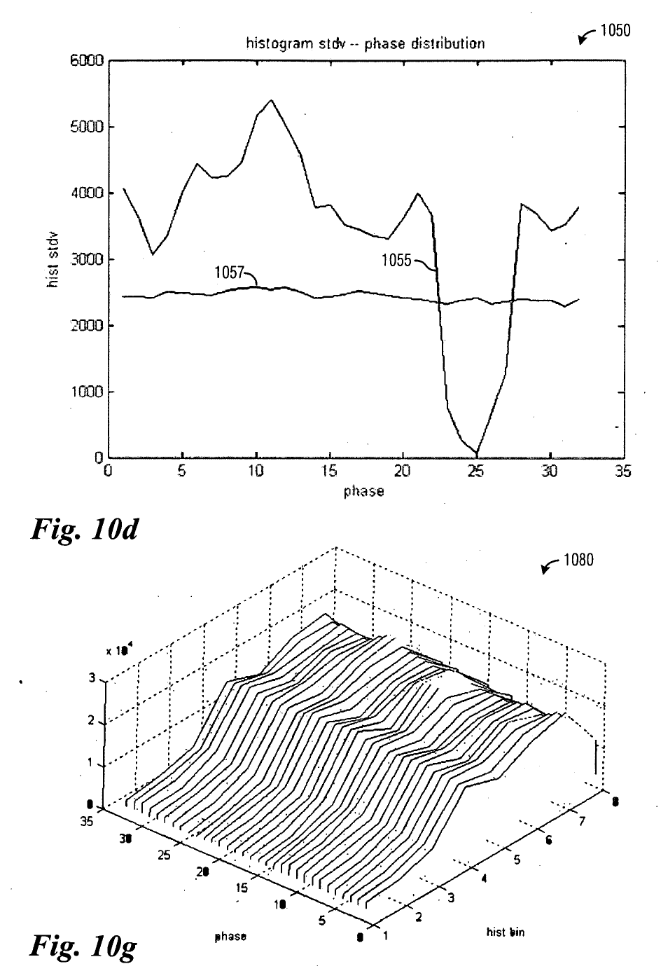

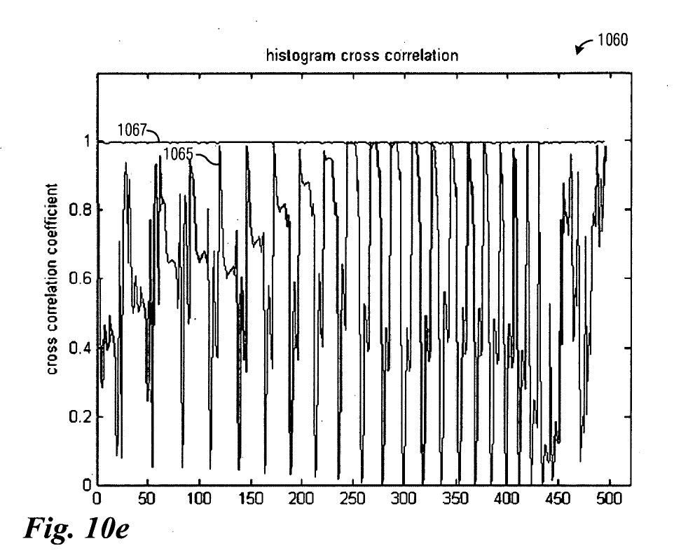

FIG. 10a illustrates a data plot 1000 of a summation of frame to frame difference versus sampling phase for an exemplary analog image signal (shown as trace 1005). The data plot 1000 illustrates a summation of frame to frame difference for a range of sampling phases. A low summation value, such as for sampling phases 0 to 20 and 28 to 31 may indicate that a relatively small number of pixels between successive images are different by more than a threshold. This may be indicative of a correct (or optimum) sampling phase. As the sampling phase approaches an incorrect (or sub-optimum) sampling phase, summation values associated with the sampling phases may begin to increase, with a maximum summation value (a peak or global maxima) corresponding to sampling phase 23.

FIG. 10b illustrates a data plot 1010 of a standard deviation of adjacent pixel difference versus sampling phase for an exemplary analog image signal (shown as trace 1015). The data plot 1010 illustrates a standard deviation of adjacent pixel difference for a range of sampling phases. A high summation value, such as for sampling phases 0 to 15 and 27 to 31 may indicate that there may be a large variation between adjacent pixel difference values. Again, this may be indicative of a correct sampling phase. As the sampling phase approaches an incorrect correct sampling phase, standard deviation values associated with the sampling phases may begin to decrease, with a minimum summation value (a valley or global minima) corresponding to sampling phase 25.

FIG. 10c illustrates a data plot 1040 of a sum of histogram bins versus sampling phase for an exemplary analog image signal. A trace 1045 illustrates a sum of histogram bins versus sampling phase for an exemplary analog image signal sampled by the ADC 450 with a correct sampling frequency and a trace 1047 illustrates a sum of histogram bins versus sampling phase for an exemplary analog image signal sampled by the ADC 450 with an incorrect sampling frequency. When a correct sampling frequency is being used to time the sampling of the exemplary analog image signal, as the sampling phase is changed, the sum of histogram bins may tend down towards zero as the sampling phase approaches a correct sampling phase (the trace 1045 approaches zero (a valley or global minima) at sampling phase 25). However, when an incorrect sampling frequency is being used to time the sampling of the exemplary analog image signal, the sum of the histogram bins may stay substantially constant independent of sampling phase.

FIG. 10d illustrates a data plot 1050 of a standard deviation of histogram bins versus sampling phase for an exemplary analog image signal. A trace 1055 illustrates a standard deviation of histogram bins versus sampling phase for an exemplary analog image signal sampled by the ADC 450 with a correct sampling frequency and a trace 1057 illustrates a standard deviation of histogram bins versus sampling phase for an exemplary analog image signal sampled by the ADC 450 with an incorrect sampling frequency. When a correct sampling frequency is being used to time the sampling of an exemplary analog image signal, as the sampling phase is changed, the standard deviation of histogram bins may tend down towards zero as the sampling phase approaches a correct sampling phase (the trace 1055 approaches zero (a valley or global minima) at sampling phase 25). However, when an incorrect sampling frequency is being used to time the sampling of an exemplary analog image signal, the standard deviation of the histogram bins may stay substantially constant independent of sampling phase.

FIG. 10e illustrates a data plot 1060 of a cross correlation of histogram bins of different phases. A cross correlation for a sampling phase may involve a computation a correlation with all other sampling phases and may be expressed mathematically as:

$$Corr ( Hist\_i , Hist\_j ) = \frac{{\sum }_{bin = 1}^{N} Hist\_i ( bin ) * Hist\_j ( bin )}{\sqrt{{\sum }_{bin = 1}^{N} {( Hist\_i ( bin ) )}^{2} * {\sum }_{bin = 1}^{N} {( Hist\_j ( bin ) )}^{2}}} ,$$

where Hist_i is a histogram for sampling phase i, and Hist_i is a histogram for sampling phase j, and the histogram for each phase will consist of N bins. The cross correlation coefficients may be computed between every two phases i and j, where i≠j. A trace 1065 illustrates a cross correlation of histogram values for an exemplary analog image signal sampled by the ADC 450 with a correct sampling frequency and a trace 1067 illustrates a cross correlation of histogram values of an exemplary analog image signal sampled by the ADC 450 with an incorrect sampling frequency. The trace 1065 shows that the cross correlation of the histogram values may vary widely, while the trace 1067 shows that the cross correlation of the histogram values may remain substantially constant when an incorrect sampling frequency is used.

In addition to analyzing the computed metrics and/or measures of the histogram bin values, the histogram bin values themselves may be analyzed to determine a correct or incorrect sampling frequency. FIG. 10f illustrates a three-dimensional data plot 1070 of histogram bin value versus histogram bin number versus sampling phase for an exemplary analog image signal sampled by the ADC 450 with a correct sampling frequency. FIG. 10g illustrates a three-dimensional data plot 1080 of histogram bin value versus histogram bin number versus sampling phase for an exemplary analog image signal sampled by the ADC 450 with an incorrect sampling frequency. The three-dimensional data plot 1070 (FIG. 10f) shows that the histogram bin values may vary dramatically for different sampling phases, while the three-dimensional data plot 1080 (FIG. 10g) shows that the histogram bin values may remain substantially consistent for different sampling phases.

Referring back to FIG. 9a, after computing the metric and/or measures (block 910), the metric and/or measures may be evaluated to select a sampling phase that yields samples that accurately represent the pixels in the analog image signal (block 915). For example, metrics and/or measures, such as a summation of frame to frame difference versus sampling phase metric (FIG. 10a), a standard deviation of adjacent pixel difference versus sampling phase metric (FIG. 10b), a sum of histogram bins versus sampling phase metric (FIG. 10c), a standard deviation of histogram bins versus sampling phase metric (FIG. 10d), a cross correlation of histogram bins (FIG. 10e), histogram bin value versus sampling phase versus histogram bin (FIG. 10f), and so forth, may be analyzed to determine if a correct sampling frequency is being used to time the sampling of the analog image signal, and if the correct sampling frequency is being used, the metric and/or measure may be used to determine a correct sampling phase.

For example, if the metric and/or measure illustrates that the value of the metric/measure remains substantially steady regardless of sampling phase, then the sampling frequency may not be substantially equal to the natural sampling frequency. If the sampling frequency is substantially equal to the natural sampling frequency, then the value of the metric/measure may vary and there may be a peak (global maxima) or valley (global minima) around one of the sampling phases. The sampling phase associated with the peak or valley may be the correct sampling phase for the analog image signal depending on the metric. If the sampling frequency is incorrect, then the determining of the sampling frequency block 505 may be repeated to reattempt the determining of the sampling frequency.

The verification of the sampling frequency may also lead to a selection of an optimum sampling phase. For example, if the metric used in verifying the sampling frequency is the sum of the histogram bins, then a data plot of the sum of the histogram bins for a verified sampling frequency may have the appearance of the trace 1045 of FIG. 10c. The optimum sampling phase may then be selected using the metric. In the case of the sum of the histogram bins, an optimum sampling phase may produce a large histogram sum value. However, for stability, adjacent sampling phases should also produce large histogram sum values. For example, in FIG. 10c, sampling phase six (6) may produce a large histogram sum value that is also surrounded by sampling phases with correspondingly large histogram sum values. The choice of a sampling phase such as sampling phase six (6) may result in relatively stable samples, because if the sampling phase should happen to drift, adjacent sampling phases may produce near optimum results.

FIG. 9c illustrates a sequence of events 960 in the selecting of an optimum sampling phase. The selecting of an optimum sampling phase may begin with a selection of a sampling phase with a corresponding large (or small) metric value (block 965). The type of metric used may determine if it may be desired that the selected sampling phase have a large or small metric value. For example, with a metric that counts a total number of times a computed adjacent pixel difference value of pixels in an image exceeds a threshold then an optimum sampling phase may have a large metric value. Conversely, with a metric that produces a negative value or decrements when a computed adjacent pixel difference value of pixels in an image exceeds a threshold, an optimum sampling phase may have a small metric value. It may be possible to compute an absolute value of the metric values. If this is done, then it may be desired that the optimum sampling phase have a large metric value.

Then, sampling phases adjacent to the selected sampling phase may be checked to determine if they have correspondingly large metric values (block 967). A number of adjacent sampling phases checked may depend on factors such as desired sampling stability, an overall number of sampling phases, and so forth. If the adjacent sampling phases have correspondingly large metric values, then the selected sampling phase is the optimum sampling phase (block 969). However, if the adjacent sampling phases do not have correspondingly large metric values, then another sampling phase may be selected (block 971) and the checking (block 967) may be repeated.

Returning now to FIG. 5, after the sampling frequency has been verified (block 515), the images in the analog image signal may be sampled at the sampling frequency and sampling phase (block 520), producing a sequence of image samples that may be processed and displayed by the display system.

FIG. 11 illustrates a sequence of events 1100 in the displaying of an analog image signal in a display system. The sequence of events 1100 may be descriptive of events occurring in a digital display device displaying images from an analog image source. The displaying of images may begin with a determining of a sampling frequency that may be used to digitize the analog image signal (block 1105). A correct sampling frequency may be important in the proper display of the images from the analog image signal since an incorrect sampling frequency may result in a distorted image.

After detecting the sampling frequency (block 1105), a sampling frequency offset may be detected (block 1110) and eliminated (block 1115). After the sampling frequency offset has been detected and eliminated, the sampling frequency may be verified (block 1120). The verifying of the sampling frequency may be achieved by creating histograms of adjacent pixel differences for a variety of sampling phases and then computing metrics and/or measures to help determine that the detected sampling frequency is a sampling frequency of the analog image signal and select a sampling phase that may result in image samples that best represents the images in the analog image signal.

With the sampling frequency verified and any sampling frequency offset eliminated, the images in the analog image sample may be sampled at the verified sampling frequency and sample phase to produce image samples (block 1125). The image samples may then be processed (block 1130) and displayed (block 1135). The sampling, processing, and displaying of the images may continue while the display devices is in operation.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for generating image data from an analog image signal, the method comprising:
detecting a sampling frequency of the analog image signal;
generating a set of histograms from samples of pixels from the analog image signal, wherein the samples are taken at the detected sampling frequency and at a different sampling phase for each of the histograms, and wherein each histogram is for samples from a single image;
using the set of histograms to determine whether the detected sampling frequency is substantially equal to a natural sampling frequency of the analog image signal; and
sampling the analog image signal at the detected sampling frequency to produce image data.

2. The method of claim 1, wherein each histogram in the set of histograms is generated from samples of pixels from a different image of the analog image signal.

3. The method of claim 1, wherein each histogram in the set of histograms is generated from samples of pixels from a different portion of the analog image signal.

4. The method of claim 1, wherein the generating a set of histograms comprises:
selecting a sampling phase from a set of sampling phases;
sampling an image of the analog image signal at the detected sampling frequency and the selected sampling phase;
computing adjacent pixel difference values for the samples;
generating a histogram from the computed adjacent pixel difference values; and
repeating the selecting, the sampling an image, the computing, and the generating a histogram for remaining sampling phases in the set of sampling phases.

5. The method of claim 3, wherein the determining whether the detected sampling frequency is substantially equal to the natural sampling frequency comprises:
computing a metric value for each histogram in the set of histograms; and
comparing the metric values to determine a relationship between the detected sampling frequency and the natural sampling frequency.

6. The method of claim 5, wherein the comparing the metric values comprises:
determining that the detected sampling frequency is not substantially equal to the natural sampling frequency if the metric values are about equal; and
determining that the detected sampling frequency is substantially equal to the natural sampling frequency if a metric value of a histogram in the set of histograms is a peak or a valley relative to other metric values, wherein the peak or the valley is substantially larger or substantially smaller relative to other metric values.

7. The method of claim 5, wherein the metric values comprise unprocessed histogram data, and wherein the comparing the metric values comprises:
determining that the detected sampling frequency is not substantially equal to the natural sampling frequency if the unprocessed histogram data for each histogram are about equal; and
determining that the detected sampling frequency is substantially equal to the natural sampling frequency if the unprocessed histogram data for each histogram vary widely.

8. The method of claim 5, wherein the metric values comprise cross-correlation coefficients of unprocessed histogram data, and wherein the comparing the metric values comprises:
determining that the detected sampling frequency is not substantially equal to the natural sampling frequency if the cross-correlation coefficients are about equal; and
determining that the detected sampling frequency is substantially equal to the natural sampling frequency if the cross-correlation coefficients vary substantially.

9. The method of claim 5, wherein the metric value is computed from a metric that is selected from the group consisting of: a summing of histogram values, an averaging of histogram values, a standard deviation of histogram values, a cross correlating of histogram values, and combinations thereof.

10. The method of claim 3, wherein the using the set of histograms further comprises, selecting a second sampling phase for the sampling the analog signal.

11. The method of claim 10, wherein the selecting the second sampling phase comprises:
selecting a first histogram having a large metric value relative to other histograms;
selecting a third sampling phase associated with the first histogram as the second sampling phase if metric values associated with histograms with sampling phases adjacent to the third sampling phase also have large metric values; and
in response to a determining that histograms with sampling phases adjacent to the third sampling phase not having large metric values,
selecting a second histogram having a large metric value relative to other histograms, and
selecting a fourth sampling phase associated with the second histogram as the second sampling phase if metric values associated with histograms with sampling phases adjacent to the fourth sampling phase also have large metric values.

12. The method of claim 1, further comprising determining if a sampling frequency offset exists in the detected sampling frequency, wherein the determining if the sampling frequency offset exists comprises:
dividing an image of the analog image signal into a plurality of columns, with each column having a width W, where W is an integer value;
selecting a column from the plurality of columns;
computing an adjacent pixel difference value for pixels in the selected column;
incrementing a counter associated with the selected column for each adjacent pixel difference value exceeding a threshold;
repeating the selecting, the computing, and the incrementing for remaining columns in the plurality of columns; and
computing the sampling frequency offset from values of the counters associated the columns in the plurality of columns.

13. The method of claim 12, further comprising removing the sampling frequency offset from the detected sampling frequency in response to a determining that the frequency offset exists.

14. A method for displaying images from an analog image signal, the method comprising:
detecting a sampling frequency of the analog image signal;
determining if the detected sampling frequency is substantially equal to a natural sampling frequency of the analog image signal using a set of histograms, wherein the set of histograms are based on adjacent pixel differences of samples of pixels from the analog image signal, wherein the samples are taken at the detected sampling frequency and at a different sampling phase for each of the histograms, and wherein each histogram is for samples from a single image;
selecting a second sampling phase of the detected sampling frequency using the set of histograms;
sampling the analog image signal at the detected sampling frequency and the second sampling phase to produce second samples;
image processing the second samples; and
displaying the processed second samples.

15. The method of claim 14, wherein the determining if the detected sampling frequency is substantially equal to the natural sampling frequency comprises:
computing a metric value for each histogram in the set of histograms;
determining that the detected sampling frequency is not substantially equal to the natural sampling frequency if the metric values are about equal; and
determining that the detected sampling frequency is substantially equal to the natural sampling frequency if a metric value of a histogram in the set of histograms is a peak or a valley relative to other metric values, wherein the peak or the valley is substantially larger or substantially smaller relative to other metric values.

16. The method of claim 14, further comprising removing a sampling frequency offset in response to a determining that the sampling frequency offset exists in the detected sampling frequency.

17. A display system comprising:
a display configured to produce images by modulating light based on image data;
an image input providing an analog image signal comprising the image data;
an image processing unit coupled to the image input, the image processing unit configured to digitize the analog image signal and to determine if a sampling frequency used to digitize the analog image signal is substantially equal to a natural sampling frequency of the analog image signal, wherein the image processing unit determines if the sampling frequency and the natural sampling frequency are substantially equal from a plurality of histograms of adjacent pixel difference values of samples taken at the sampling frequency and at different sampling phases for each histogram, and wherein each histogram is for samples from a single image; and
a controller coupled to the image processing unit and to the display, the controller configured to control the operation of the display based on the image data.

18. The display system of claim 17, wherein the image processing unit is further configured to select a sampling phase and to remove a sampling frequency offset in the detected sampling frequency if the sampling frequency offset exists.

19. The display system of claim 17, wherein the image processing unit comprises:
an analog-to-digital converter (ADC) coupled to the image input, the ADC to digitize the analog image signal at the sampling frequency provided and a sampling phase provided by a clock; and
a tuning unit coupled to the ADC, the tuning unit configured to determine if the sampling frequency used to digitize the analog image signal is substantial equal to the natural sampling frequency.

20. The display system of claim 19, wherein the tuning unit comprises:
a phase adjust unit configured to adjust a sampling phase of samples made by the ADC;
a pixel difference unit coupled to the histogram unit, the pixel difference unit configured to compute an intensity difference between adjacent pixels in an image or between a single pixel in consecutive frames;
a histogram unit coupled to the phase adjust unit, the histogram unit configured to compute a histogram of the intensity difference computed by the pixel difference unit; and
a metric calculator coupled to the histogram unit, the metric calculator configured to compute a metric or a measure of data computed by the histogram unit.
